(19) United States
(12) Patent Application Publication
(10) Pub. No.: US 2025/0357182 A1
(43) Pub. Date: Nov. 20, 2025

(54) Workpiece Surface Processing System for Semiconductor Wafers

(71) Applicant: Wolfspeed, Inc., Durham, NC (US)

(72) Inventors: Simon Bubel, Carrboro, NC (US); Dinusha Priyadarshani Karunaratne, Cary, NC (US)

(21) Appl. No.: 18/663,862

(22) Filed: May 14, 2024

(51) Int. Cl. H01L 21/687; H01L 21/67; H01L 21/683

(52) U.S. Cl. CPC H01L 21/68785; H01L 21/67092; H01L 21/6838; H01L 21/68721; H01L 21/68757

(57) ABSTRACT

Systems and methods for surface processing of a semiconductor workpiece, such as a silicon carbide semiconductor wafer, are provided. An example surface processing system includes a platen configured to rotate about an axis. The example surface processing system includes a surface processing pad on the platen. The example surface processing system includes a workpiece carrier operable to bring a semiconductor workpiece into contact with the surface processing pad. The workpiece carrier includes a head and a retaining ring around at least a portion of the head. At least one of the head and the retaining ring is movable relative to each other.

### FIELD

The present disclosure relates generally to semiconductor workpieces, and more particularly to surface processing systems for semiconductor workpieces, such as silicon carbide semiconductor wafers.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices.

Power semiconductor devices may be packaged into various semiconductor device packages, such as discrete semiconductor device packages and power modules. Power modules may include one or more power devices and other circuit components and can be used, for instance, to dynamically switch large amounts of power through various components, such as motors, inverters, generators, and the like.

Semiconductor devices may be fabricated from wide bandgap semiconductor materials, such as silicon carbide and/or group III-nitride based semiconductor materials. The fabrication process for power semiconductor devices may require processing of wide bandgap semiconductor wafers, such as silicon carbide semiconductor wafers.

### SUMMARY

Aspects and advantages of embodiments of the present disclosure will be set forth in part in the following description, or may be learned from the description, or may be learned through practice of the embodiments.

One example aspect of the present disclosure is directed to a surface processing system. In some implementations, the example surface processing system includes a platen configured to rotate about an axis. In some implementations, the example surface processing system includes a surface processing pad on the platen. In some implementations, the example surface processing system includes a workpiece carrier operable to bring a semiconductor workpiece into contact with the surface processing pad. The workpiece carrier includes a head and a retaining ring around at least a portion of the head. At least one of the head and the retaining ring is movable relative to each other.

Another example aspect of the present disclosure provides an example method. In some implementations, the example method includes providing a silicon carbide semiconductor workpiece against a surface processing pad with a workpiece carrier, the workpiece carrier includes a head and a retaining ring around at least a portion of the head. In some implementations, the example method includes imparting relative motion between the retaining ring and the head. In some implementations, the example method includes performing a surface processing operation by imparting relative motion between the surface processing pad and the silicon carbide semiconductor workpiece.

Another example aspect of the present disclosure is directed to a retaining ring for a workpiece carrier in a system for polishing semiconductor workpieces. In some implementations, the example retaining ring includes a plurality of grooves. In some implementations, the plurality of grooves are at different vertical positions along of the retaining ring.

Another example aspect of the present disclosure is directed to an example surface processing system. In some implementations, the example surface processing system includes a platen operable to rotate about an axis. In some implementations, the example surface processing system includes a surface processing pad on the platen. In some implementations, the example surface processing system includes a bias source. In some implementations, the example surface processing system includes a workpiece carrier operable to bring a semiconductor workpiece into contact with the surface processing pad. The workpiece carrier includes a head and a retaining ring around at least a portion of the head. In some implementations, the head is operable to provide an electrically conductive path through the head to the bias source.

Another example aspect of the present disclosure is directed to a retaining ring for a workpiece carrier in a system for polishing semiconductor workpieces. The retaining ring has a height in a range from about 5 millimeters to about 100 millimeters.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts an example semiconductor wafer surface processing system according to example embodiments of the present disclosure;

FIG. 2A depicts a cross-sectional view of an example workpiece carrier according to example embodiments of the present disclosure;

FIG. 2B depicts a cross-sectional view of an example workpiece carrier according to example embodiments of the present disclosure;

FIG. 3A depicts a cross-sectional view of an example workpiece carrier according to example embodiments of the present disclosure;

FIG. 3B depicts a cross-sectional view of an example workpiece carrier according to example embodiments of the present disclosure;

FIGS. 4A and 4B depict plan views of example grooves through a retaining ring according to example embodiments of the present disclosure;

FIGS. 5A and 5B depicts example arrangement of grooves on a surface of a retaining ring according to example embodiments of the present disclosure; and

FIG. 6 depicts a cross-sectional view of an example workpiece carrier according to example embodiments of the present disclosure;

FIG. 7 depicts a cross-sectional view of an example workpiece carrier according to example embodiments of the present disclosure;

FIGS. 8A, 8B, 8C, and 8D depict example pressure zones of a workpieces carrier according to example embodiments of the present disclosure; and

FIG. 9 depicts a flow diagram of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Power semiconductor devices are often fabricated from wide bandgap semiconductor materials, such as silicon carbide or Group III-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that example embodiments of the present disclosure may be used with any semiconductor material, such as other wide bandgap semiconductor materials, without deviating from the scope of the present disclosure. Example wide bandgap semiconductor materials include silicon carbide and the Group III-nitrides.

Power semiconductor devices may be fabricated using epitaxial layers formed on a semiconductor workpiece, such as a silicon carbide semiconductor wafer. Power semiconductor device fabrication processes may include surface processing operations that are performed on the silicon carbide semiconductor wafer to prepare one or more surfaces of the silicon carbide semiconductor wafer for later processing steps, such as surface implantation, formation of epitaxial layers, metallization, etc. Example surface processing operations may include grinding operations, lapping operations, and polishing operations.

Aspects of the present disclosure are discussed with reference to a semiconductor workpiece that is a semiconductor wafer that includes silicon carbide (“silicon carbide semiconductor wafer”) for purposes of illustration and discussion. Those of ordinary skill in the art, using the disclosures provided herein, will understand that aspects of the present disclosure can be used with other semiconductor workpieces. Other semiconductor workpieces may include carrier substrates, ingots, boules, polycrystalline substrates, monocrystalline substrates, bulk crystalline material having a thickness of greater than about 1 mm, such as greater than about 5 mm, such as greater than about 10 mm, such as greater than about 20 mm, such as greater than about 50 mm, such as greater than about 100 mm, to 200 mm, etc.

In some examples, the semiconductor workpiece includes silicon carbide crystalline material. The silicon carbide crystalline material may have a 4H crystal structure, 6H crystal structure, or other crystal structure. The semiconductor workpiece can be an on-axis workpiece (e.g., end face parallel to the (0001) plane) or an off-axis workpiece (e.g., end face non-parallel to the (0001) plane).

Aspects of the present disclosure may make reference to a surface of the semiconductor workpiece. In some examples, the surface of the workpiece may be, for instance, a silicon face of the workpiece. In some examples, the surface of the workpiece may be, for instance, a carbon face of the workpiece.

In some examples, a semiconductor wafer may be a solid semiconductor workpiece upon which semiconductor device fabrication may be implemented. A semiconductor wafer may be a homogenous material, such as silicon carbide, and may provide mechanical support for the formation and/or carrying of additional semiconductor layers (e.g., epitaxial layers), metallization layers, and other layers to form one or more semiconductor devices. In some examples, a semiconductor wafer may have a thickness in a range of about 0.5 microns to about 1000 microns or greater, such as in a range of about 150 microns to about 400 microns, such as in a range of about 250 microns to about 350 microns. In some examples, the semiconductor wafer may include a thin semiconductor layer (e.g., about 0.5 micron or less, such as 0.1 microns to about 0.5 microns) on a carrier substrate.

A semiconductor wafer may be characterized by a plurality of surfaces. For example, a semiconductor wafer may have a “first major surface” and a “second major surface.” The first major surface may be generally opposite the second major surface. The first and second major surfaces may be generally parallel to one another. A semiconductor wafer may also have a “side surface” corresponding to a surface extending between the two major surfaces. For example, the side surface may extend between the first major surface and the second major surface.

Grinding is a material removal process that is used to remove material from the semiconductor wafer. Grinding may be used to reduce a thickness of a semiconductor wafer. Grinding typically involves exposing the semiconductor wafer to an abrasive containing surface, such as grind teeth on a grind wheel. Grinding may remove material of the semiconductor wafer through engagement with the abrasive surface.

Lapping is a precision finishing process that uses a loose abrasive in slurry form. The slurry typically includes coarser particles (e.g., largest dimension of the particles being greater than about 100 microns) to remove material from the semiconductor wafer. Lapping typically does not include engaging the semiconductor wafer with an abrasive-containing surface on the lapping tool (e.g., a wheel or disk having an abrasive-containing surface). Instead, the semiconductor wafer typically comes into contact with a lapping plate or a tile usually made of metal. Lapping typically provides better planarization of the semiconductor wafer relative to grinding.

Polishing is a process to remove imperfections and create a very smooth surface with a low surface roughness. Polishing may be performed using a slurry and a polishing pad. The slurry typically includes finer particles relative to lapping, but coarser particles relative to chemical mechanical planarization (CMP). Polishing typically provides better planarization of the semiconductor wafer relative to grinding.

CMP is a type of fine or ultrafine polishing, typically used to produce a smoother surface ready, for instance, for epitaxial growth of layers on the semiconductor wafer. CMP may be performed chemically and/or mechanically to remove imperfections and to create a very smooth and flat surface with low surface roughness. CMP typically involves changing the material of the semiconductor through a chemical process (e.g., oxidation) and removing the new material from the semiconductor wafer through abrasive contact with a slurry and/or other abrasive surface or polishing pad (e.g., oxide removal). In CMP, the abrasive elements in the slurry typically remove the product of the chemical process and do not remove the bulk material of the semiconductor wafer, often leaving very low subsurface damage.

Polishing tools (e.g., such as chemical mechanical polishing (CMP) tools) may be used after grinding operations to polish and/or smooth a semiconductor wafer surface. Polishing tools, such as CMP tools, may use a combination of chemical and mechanical forces to remove excess materials from a wafer surface, ensuring desired flatness and smoothness. Polishing tools, such as CMP tools, may include a rotating platen, polishing pad, and a slurry containing abrasive particles and chemical agents. As the wafer is pressed against the polishing pad and rotated, the slurry chemically reacts with and/or mechanically removes material, resulting in a highly planar and smooth surface.

Electrochemical Mechanical Polishing (ECMP) is a specialized process used in semiconductor manufacturing for polishing and planarizing surfaces with high precision. ECMP combines the principles of electrochemical and mechanical actions to achieve highly uniform material removal rates across the surface of a semiconductor wafer. For example, a silicon carbide semiconductor wafer may be mounted to a workpiece carrier, which may bring the semiconductor wafer into contact with a polishing pad. A slurry (including an electrolyte solution) can be applied between the wafer and the polishing pad to facilitate the electrochemical reactions, carry away removed material, and provide lubrication for the mechanical polishing action. A bias (e.g., bias voltage and/or bias current) may be applied between the semiconductor wafer and the electrolyte solution of the slurry to drive electrochemical reactions to occur at the surface of the semiconductor wafer, leading to material dissolution. The electrochemical reactions may vary depending on the specific materials involved, but they often involve oxidation or reduction processes.

For ECMP, while the electrochemical reactions are occurring, mechanical forces may be applied to the wafer through the polishing pad. These mechanical forces help to enhance material removal and ensure a uniform polishing action across the substrate surface. As the ECMP process continues, material is gradually removed from the surface of the workpiece, resulting in planarization and smoothing of the surface. The combination of electrochemical and mechanical actions allows for precise control over material removal rates and surface finish (e.g., through control of bias (e.g., bias voltage, bias current) applied to the semiconductor wafer.

Surface processing of silicon carbide semiconductor wafers may pose several challenges due to the inherent properties of the material. Silicon carbide is an extremely hard and brittle compound with a high level of abrasiveness, making the polishing process more demanding. One challenge is the potential for excessive tool wear and heat generation during surface processing, which may affect the quality of the finished product. The hardness of silicon carbide may also lead to the formation of cracks or fractures if not properly managed, impacting the structural integrity of the material. Additionally, achieving precise dimensions and surface finishes may be challenging due to the resistance of silicon carbide to abrasion. Controlling parameters such as polishing pad selection, rotational speed, slurry composition, downforce, and/or cooling mechanisms may be important to overcoming these challenges and ensuring the successful fabrication of silicon carbide components with the desired properties and performance.

Current single side polishing processes for non-batch wafer processing, such as abrasive slurry processes, CMP and ECMP, employ a workpiece carrier system that includes a head and a retaining ring for holding the wafer during processing. The head exerts a downforce to the back of the workpiece (e.g., non-processing side) and presses the other side of the workpiece (e.g., the processing side) onto a surface processing pad (e.g., polishing pad). The head may also be configured to rotate and translate the workpiece on a rotating surface processing pad (e.g., polishing pad). The workpiece carrier system may include a retaining ring around the head. The retaining ring may generally have an inner diameter matched to the outer diameter of the workpiece during a surface processing operation so that the retaining ring may hold the semiconductor wafer in place during the surface processing operation.

For instance, the retaining ring may reduce pad rebounding, thus preventing removal nonuniformity around the semiconductor workpiece edge. The workpiece may spin freely under the head but does not slip off the head as it is retained in place by the retaining ring. However, there may be challenges when processing silicon carbide semiconductor wafers. This is at least partially due to the aggressive nature of the silicon carbide ECMP or CMP processes. For instance, the downforce exerted by the head is often applied to both the head and the retaining ring, which causes the retaining ring to be consumed at increased rates. Further, exerting the increased down pressure of the head on the retaining ring creates unnecessary friction and contributes to pad heating.

According to example aspects of the present disclosure, a surface processing system may include a workpiece carrier having a retaining ring configured to exert downforce pressure independently from the head. Further, the retaining ring and/or the head may be movable/adjustable relative to one another (e.g., in a direction generally perpendicular to the surface processing pad). For instance, in some examples, the retaining ring may be movable relative to the head. In some examples, the head may be movable relative to the retaining ring. In some examples, the head and the retaining ring may be movable relative to each other. Such a configuration may reduce unnecessary friction and heating on the processing pad during a surface processing operation.

Further, in some examples, the head of the example workpiece carriers may include a thermally and/or electrically conductive path that is in contact with the non-processing side of the workpiece during a surface processing operation. In such a manner, the head may be cooled during surface processing to further help reduce temperature increases during the surface process operation. Additionally, the head may provide an electrically conductive contact to provide an electrical bias from a bias source (e.g., voltage source and/or current source) through the head to the workpiece, for instance, to implement an ECMP process. For instance, the semiconductor workpiece may have a first side that remains in electrically conductive contract with the head during a surface processing operation.

Accordingly, example aspects of the present disclosure are directed to surface processing systems (e.g., polishing tools or grinding tools) that are adapted to implement one or more surface processing operations on a semiconductor workpiece (e.g., silicon carbide semiconductor wafer). The surface processing system may include a platen configured to rotate about an axis and a surface processing pad disposed on the platen. A workpiece carrier is operable to bring a semiconductor workpiece into contact with the surface of the surface processing pad. The workpiece carrier includes a head and a retaining ring around at least a portion of the head. The retaining ring and/or the head are movable in one or more directions relative to each other. Accordingly, the downforce pressure applied by the head may have a different magnitude from the downforce pressure applied by the retaining ring on the surface processing pad. In other aspects the head may be configured to rotate about an axis independently from the retaining ring. A slurry may be provided to provide mechanical polishing. The slurry may contain one or more abrasive elements as described below. During a polishing operation, the abrasive elements of the slurry may remove material from the semiconductor workpiece. As discussed below, in some examples, the slurry may include an oxidizing material and/or an electrolyte.

In some examples, the head includes an electrically conductive material that provides an electrically conductive path that is in electrically conductive contact with one side of the workpiece during a surface processing operation. In this way, the head may provide an electrically conductive path from the semiconductor workpiece to a bias source (e.g., voltage source and/or current source). The bias source may be configured to provide a bias voltage and/or a bias current between the semiconductor workpiece and, for instance, an electrolyte solution. The head may provide an electrically conductive path for one or more charge carriers from the workpiece to the bias source. As used herein, charge carriers may be, for instance, ions, electrons, protons, or other particles carrying a charge. In some examples, an electrical circuit is provided through the bias source, an electrolyte (e.g., slurry with electrolyte solution), the semiconductor wafer, and the electrically conductive pathway in the head.

The surface processing system may include a delivery system that may deposit materials onto the surface processing pad. For example, the surface processing system may include a slurry delivery system that deposits a slurry onto the surface processing pad. The slurry may include abrasive particles that allow a surface polishing pad to physically remove material from the surface, aiding in material removal and achieving the desired surface finish. These abrasive particles may include fine-grained materials such as silicon dioxide (SiO₂), alumina (Al₂O₃), ceria (CeO₂), or other suitable nanoparticles or microparticles (e.g., KMgO₄), including those created during operation (e.g., MgO particles through decomposition of KMgO₄). The slurry may also include an electrolyte that includes charge carriers, such as ions, electrons, protons or other particles carrying a charge, which may be used to facilitate the electrically conductive path through the workpiece and head according to the technology of the present disclosure.

In some embodiments, the slurry may provide for enhancing abrasive particle stabilization, electrolytic conduction, and electrochemical activity by ionic compound design. The use of tailored ionic components may allow for stabilization of the particles within the slurry. Tailoring the ionic components may be achieved by selecting cations and anions for their respective tasks for stabilizing the abrasive particle and creating an efficient electrochemical reaction. One ionic species (e.g., the cation) can bond to the abrasive particle via a direct or induced electrostatic or covalent attraction, while the anion can be tailored for highest effectivity regarding ionic conductivity and kinetics at the workpiece surface. As such, the slurry is tuned for effective polishing/grinding processes and, advantageously, does not create the environmental and safety concerns of strong oxidizers.

For instance, in some examples, a slurry may include an organic cation that can stabilize an abrasive particle within the slurry and provide the desired electrochemical properties may use a well-established chemical pathway for forming solution stable electron deficient organic species (i.e., cations). This synthetic approach uses the ability of neutral electron rich atoms, such as nitrogen, oxygen, sulfur, and phosphorous, to form sigma bonds to carbon to produce a solution stable organic cation. A neutral aromatic nitrogen, for example, can produce a stable single bond to carbon where the electron is shared between the two atoms and a net positive charge resides on the nitrogen. Such organic cations are utilized in the field of organic electrochemistry for their charged ground state and reversible redox states. The cations are paired with a carefully chosen anion to tune chemical properties like solubility and aggregation. In the solid state, they can reside as stable ionic solids, analogous to inorganic salts. These electron deficient species are tunable through molecular design to achieve the desired electrochemical properties. The positive charge functions as the primary stabilizer for abrasive slurry particles in the slurry. To this core molecular design for the cation, carefully chosen constituents are appended which serve to link the molecule to the abrasive particle, tune polarity, and optimize steric effects.

In some example embodiments, a small anion is paired with the cation to allow for effective oxidation of partially oxidized or rough surfaces of the semiconductor workpiece. The oxidized layer (e.g., of SiO₂ or other oxides including mixed oxides such as SiC: SiO₂) formed electrochemically on the semiconductor workpiece then needs to be removed chemically and/or mechanically to avoid passivation and to expose the fresh wafer surface for continuous electrochemical oxidation. In this regard, the abrasives in the slurry may interact with the oxidized layers via adsorption (chemisorption, physisorption, magnetic attraction, and/or others) and, along with the pad action, help to mechanically break down the oxidized layer to aid material removal. Some abrasive types, such as ceria, can even chemically bind to SiO₂ and facilitate material removal.

In some embodiments, some or all of the abrasive particles in the slurry can be provided to the slurry from the polishing pad or a grind disk material. For example, they may be released from the pad during a conditioning process and will be affected by the choice of anionic/cationic compounds in the slurry.

In some embodiments, the cations/anions can exhibit stabilization and attachment functions that include steric, ionic, oleophilic, or hydrophilic properties. For example, the cations or anions may function as surfactants, which are capable of sterically or electrostatically stabilizing the abrasive particles in the slurry. Surfactants may also be added to the slurry as an additional component. Depending on the pH and the isoelectric points of the workpiece (e.g., SiC wafer) and the abrasive, either cationic or anionic surfactants can be used to stabilize negatively or positively charged abrasive particles, respectively. Zwitterionic surfactants, containing both cationic and anionic activity, can also be used for the same purpose, and the cationic or anionic nature of such zwitterionic surfactants can be controlled by the slurry pH. Moreover, surfactants may be water soluble, allowing the slurry to be an aqueous medium, providing the polar protic chemical environment ideal for an ECMP slurry, while offering the advantage of steric hindrance to stabilize abrasives.

In some embodiments, ionic compounds like NaCl, NaNO₃, KCl, NaNO₃, or NH₄F can be added as electrolyte components in which Na+, K+, or NH₄+ form cations and Cl—, NO3-, or F— form anions to increase the ionic strength of the slurry. The strong ionic nature of such an ECMP slurry may have added benefits to further enhance the chemical dissolution of the oxidized layer formed during ECMP. For example, when the oxidized layer contains SiO₂, the anions may act as strong nucleophiles or electron rich species to chemically attack the electron deficient Si atom of SiO₂ to promote bond breaking and hydrolysis, leading to the formation of soluble silica species such as silicic acid. Protonation and deprotonation of these soluble silica species may further enhance the ionic and nucleophilic activity of the ECMP slurry.

In some examples, the head may further include one or more vacuum lines and/or apertures configured to create a vacuum between the head and the semiconductor workpiece. In addition, and/or in the alternative, the head may further include a porous material that allows a vacuum to be applied through the head. The vacuum may be used to hold (e.g., chuck) the workpiece to the head during a surface processing operation.

In some examples, the head may be configured to modify a pressure between the semiconductor workpiece and surface processing pad. For instance, one or more cavities configured to hold a fluid may be within the head. The amount of fluid in each of the cavities may be modified to modify the pressure between the workpiece and the surface processing pad during the surface processing operation. For instance, to increase the pressure, additional fluid may be provided to one or more of the cavities. Similarly, to decrease the pressure, fluid may be removed from one or more of the cavities. Accordingly, each cavity may define a pressure zone that may be modified independently from each other. In some examples, the head may include multiple cavities to provide a plurality of different pressure zones for the workpiece carrier.

In some examples, the retaining ring may be formed from a wearable material. For instance, the retaining ring may be formed from a thermoplastic material, such as a polyaryletherketone (e.g., polyether ether ketone) or one or more polyaryletherketones (e.g., polyether ether ketone). In some examples, the retaining ring may include one or more grooves, each positioned at a different circumferential position of the retaining ring. During processing, the grooves allow for the flow of fluids (e.g., slurry, such as electrolyte slurry) to and from the workpiece. During surface processing as the retaining ring is worn, grooves may be eliminated. The retaining ring according to some examples of the present disclosure, however, has additional grooves at taller heights which may open up as lower grooves have been worn away. In some examples, the retaining ring may also include an abrasive-containing material that may condition the surface processing pad during the surface processing operation.

Aspects of the present disclosure provide a number of technical effects and benefits. For instance, use of a retaining ring in conjunction with a workpiece carrier that is translatable independently from the head of the workpiece carrier may reduce wear and consumable costs in addition to reducing downtime of the surface processing system (e.g., to replace the worn retaining rings). Further, the head may include a thermally conductive material that allows for further cooling of the workpiece, surface processing pad, and other components of the surface processing system via the thermally conductive path through the head. Additionally, the head may include or may provide an electrically conductive pathway for charge carriers, thus reducing the need for additional materials and electrodes within the surface processing system to provide a bias (e.g., bias voltage and/or bias current) for an ECMP operation. Pressure adjustments on the semiconductor workpiece may be modified using cavities disposed within the head, further reducing the need for additional membranes between the head and the workpiece, thus saving consumable cost and tool downtime.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure may refer to a “pad.” In some cases, a pad with increased stiffness, thickness, or other attributes may be commonly referred to as a “disk.” However, in the present disclosure, the terms “pad” and “disk” may be used interchangeably without altering the scope of the present disclosure.

In the drawings and specification, there have been disclosed typical embodiments and, although specific terms are employed, they are used in a generic and descriptive sense only and not for purposes of limitation of the scope set forth in the following claims.

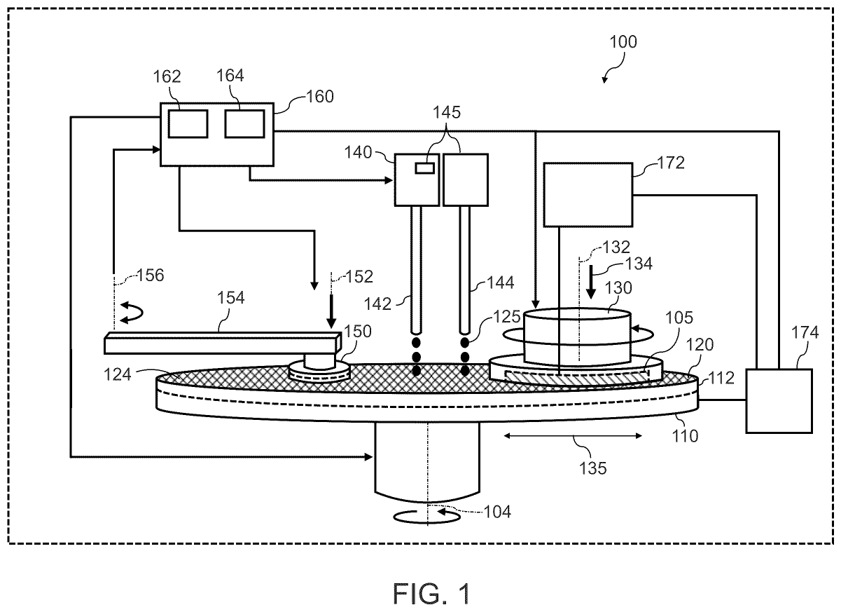

FIG. 1 depicts an example surface processing system 100 for a semiconductor workpiece 105 according to example embodiments of the present disclosure. The surface processing system 100 may be operable to perform a surface processing operation (e.g., a polishing operation (ECMP or CMP) or a grinding operation) for a semiconductor workpiece 105. The semiconductor workpiece 105 may be a silicon carbide semiconductor workpiece such as, for example, a silicon carbide wafer. The semiconductor workpiece 105 may include 4H silicon carbide, 6H silicon carbide or other crystal structure. The silicon carbide workpiece 105 may be doped or undoped. The surface processing system 100 includes a platen 110, a surface processing pad 120, a workpiece carrier 130, a fluid delivery system 140, a conditioning head 150, and a controller 160. In some examples, the surface processing system 100 additionally includes a bias source 174 (e.g., voltage source and/or a current source) for providing a bias current or a bias voltage to the workpiece 105 during an ECMP operation.

More specifically, the surface processing system 100 includes the platen 110. The platen 110 may be operable to rotate about an axis 104. The platen 110 may be operable to rotate about the axis 104 in either a clockwise or counterclockwise direction. In some examples, the platen 110 may rotate, for instance, at a rotational speed in a range of about 15 rpm to about 10000 rpm, such as about 40 rpm to about 7500 rpm, such as about 40 rpm to about 2000 rpm, such as about 40 rpm to about 1000 rpm, such as about 40 rpm to about 500 rpm, such as about 40 rpm to about 120 rpm. Higher rotational speeds, such as between 200 rpm and 10000 rpm may be beneficial for grinding process(s) using a surface processing system (e.g., with a grind disc) according to examples of the present disclosure.

The platen 110 may include a receptacle 112. The receptacle 112 may typically be configured to hold a surface processing pad 120 (e.g., polishing pad) for a polishing process (e.g., a CMP process or an ECMP process). The receptacle 112 may be a surface configured to support or receive the surface processing pad 120. In some examples, the receptacle 112 may be a planar surface that supports the surface processing pad 120.

The surface processing pad 120 may be configured to polish or grind silicon carbide. For instance, for a grinding operation the surface processing pad 120 may be a grind disk. For a polishing operation, the surface processing pad 120 may be a polishing pad. The surface processing pad 120 may have a first surface and an opposing second surface. The second surface may face the platen 110 such that the first surface is exposed for grinding the semiconductor workpiece 105. In examples where the surface processing pad 120 is a grind disc, the first surface of the surface processing pad 120 may include a continuous surface of an abrasive containing material such that at least 75% of a surface area of the first surface of the surface processing pad 120 is an abrasive containing material having a plurality of abrasive elements (e.g., abrasive particles), such as at least 85% of the surface area of the first surface of the surface processing pad 120, such as at least 95% of the surface area of the first surface the surface processing pad 120. In this way, substantially the entire surface of the surface processing pad 120 (e.g., in this example a grind disc) provides an abrasive surface for a grinding operation.

The abrasive containing material of the surface processing pad 120 may be sufficient to perform a grinding operation on silicon carbide. In some embodiments, the grinding operation may be a coarse grinding operation or a fine grinding operation. The abrasive containing material may include a plurality of abrasive elements (e.g., abrasive particles) in a host material or matrix. In some examples, the host material may include one or more of vitreous material, metal, resin, and/or other sintered material and/or organic material. In some examples, the abrasive elements may be diamond or a diamond coated material. In some examples, the abrasive elements may include a ceramic material. Example ceramic materials may include, for instance, boron carbide (B₄C) and cubic boron nitride (BN). In some examples, the abrasive elements may include one or more metal oxides (sintered and/or unsintered). In some embodiments, the abrasive elements may include silica, ceria, zirconia, alumina, silicon carbide, nitrates, and/or other carbides and in general one or more of: (i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide.

In some examples, the abrasive elements of the surface processing pad 120 may have a hardness in a range of about 7 Mohs to about 10 Mohs, such as about 10 Mohs. In some examples, the abrasive elements of the surface processing pad 120 may include a plurality of abrasive particles. In some examples, the abrasive elements of the surface processing pad 120 may have a grit size. The grit size of the abrasive elements may be in a range of about FEPA grit size F500 to about FEPA grit size F90,000, such as a range of about FEPA grit size F500 to about FEPA grit size F14000, such as about FEPA grit size F600 to about FEPA grit size F1200.

In some embodiments, the surface processing operation may include a polishing operation (e.g., a CMP operation or an ECMP operation). During a polishing operation, the surface processing pad 120 may provide a surface for polishing the semiconductor workpiece 105. The surface processing pad 120 may include durable and chemically resistant materials such as polyurethane and/or polyether ether ketone (PEEK) material. The surface processing pad 120 may have a surface with a specified roughness and porosity to facilitate polishing a semiconductor workpiece 105 (e.g., a silicon carbide semiconductor wafer).

The surface processing pad 120 may have one or more wear-resistant layers (e.g., diamond layers, diamond-like carbon layers, ceramic layers, etc.). The surface processing pad 120 may include grooves or dimples to increase slurry distribution and reduce edge effects during the polishing process (e.g., CMP process or ECMP process).

In some examples, the surface processing pad 120 may provide an electrically conductive path for one or more charge carriers through the surface processing pad 120 to a bias source 174, allowing for charge carriers to move from the surface, side, or backside of the surface processing pad 120 to the surface of a workpiece. Methods of conduction of charge carriers can include transport of electrons or holes, ionic conduction of protons or other ions, fluid transport of any particles carrying a charge. Charge transport may be a general property, independent of the driving forces such as electric potential, diffusion, or thermal-, pressure-, and other gradients.

In some examples, the resistivity of the electrically conductive path through a thickness of the polishing pad 120 may be in a range of about 1 microOhm/cm² to about 500 Ohm/cm². The resistivity through the thickness of the polishing pad 120 may be different for different types of charge carriers. In some examples, the resistivity of the electrically conductive path through a thickness of the polishing pad 120 may be in a range from about 1 microOhm/cm² to about 0.1 Ohm/cm². In some examples, the resistivity of the electrically conductive path through a thickness of the polishing pad 120 may be in a range from about 0.1 Ohm/cm² to about 200 Ohm/cm², such as about 1 Ohm/cm² to about 100 Ohm/cm², such as about 2 Ohm/cm² to about 50 Ohm/cm². In some examples, the resistivity of the electrically conductive path through a thickness of the polishing pad 120 may be in a range from about 0.1 Ohm/cm² to about 500 Ohm/cm², such as about 2 Ohm/cm² to about 200 Ohm/cm², such as about 4 Ohm/cm² to about 100 Ohm/cm².

In some examples the polishing pad 120 may have a sheet resistance in a radial direction of the polishing pad in a range of about 6 microOhm·m/m to about 200 Ohm·m/m. The sheet resistance in the radial direction of the polishing pad 120 may be different for different types of charge carriers. In some examples, the polishing pad 120 may have a sheet resistance in a range of about 6 microOhm·m/m to about 250 milliOhm·m/m. In some examples, the polishing pad 120 may have a sheet resistance in a range of about 0.25 Ohm·m/m to about 2.0 Ohm·m/m, such as about 0.5 Ohm·m/m to about 1 Ohm·m/m, such as about 0.5 Ohm·m/m to about 0.75 Ohm·m/m in a radial direction of the polishing pad 120. In some examples, the polishing pad 120 may have a sheet resistance in a range of about 0.25 Ohm·m/m to about 200 Ohm·m/m, such as about 0.5 Ohm·m/m to about 100 Ohm·m/m, such as about 0.5 Ohm· m/m to about 75 Ohm·m/m in a radial direction of the polishing pad 120. The electrically conductive path provided by the polishing pad 120 in these ranges may provide for greater uniformity in the electrochemical reactions occurring at the workpiece 105.

In some examples, the material of the polishing pad 120 may include metal or metallic elements, a matrix, or metal bonds. The metal materials can contain catalysts that may be used to activate chemistry that contributes to the oxidation of the workpiece 105. Those metals may include, for instance, noble metals, such as platinum, gold, silver, palladium, or other metals and their oxides, such as ruthenium, iridium, iron, nickel, copper, or aluminum. In these cases, the electrical resistivity through a thickness of the polishing pad 120 can be in the range of 1 micro-Ohm/cm² to 100 milli-Ohm/cm² or higher, and the sheet resistance in a radial direction can be in a range of 6 microOhm m/m to about 250 milliOhm m/m or higher.

In some examples, a surface polishing pad with a large resistance may be compensated with the increased flow of electrolyte (e.g., electrolyte slurry). This may allow the electrolyte fluid to move through voids (e.g., open pore system, channels, apertures, holes, etc.) in the surface processing pad 120, contributing to conductive paths in the surface processing pad 120.

The surface processing pad 120 may include a cushioning layer (e.g., foam or rubber), in some examples, to facilitate adaptation of the surface processing pad 120 to the topography of the semiconductor workpiece 105, providing improved planarization of the semiconductor workpiece 105.

In some examples, the surface processing pad 120 has an abrasive storing material. The abrasive storing material may hold abrasive particles or elements (e.g., from a slurry used in a polishing operation, such as a CMP operation or ECMP operation). The abrasive particles or elements held by the surface processing pad 120 may provide an abrasive surface for performing a surface processing operation. In some examples, the surface processing pad 120 does not include a surface with abrasive elements.

In some examples, the surface processing pad 120 may have a diameter that is greater than a diameter of the semiconductor workpiece 105. The surface processing pad 120 may have a diameter in a range of, for instance, about 150 millimeters to about 820 millimeters, such as in a range of about 150 millimeters to about 400 millimeters, such as in a range of about 150 millimeters to about 300 millimeters. In some examples, the diameter of the surface processing pad 120 may be smaller or nearly the same size as the diameter of the platen 110 (FIG. 1). However, the diameter of the surface processing pad 120 may be larger than the diameter of the platen 110 without deviating from the scope of the present disclosure. In some examples, the surface processing pad 120 may have a thickness in a range of about 1 millimeters to about 40 millimeters, such as in a range 1 millimeters to about 20 millimeters, such as in a range of about 1 millimeters to about 7 millimeters.

In some examples, the surface processing pad 120 may include an additive (not shown). The additive may be added as a liquid or a powder to the surface processing pad 120 prior to or during a grinding operation. In some examples, the additive is embedded as part of the surface processing pad 120, such as interspersed among abrasive containing material 124 in the surface processing pad 120. The additive may be in the form of a liquid and/or a solid (e.g., powder) on the surface processing pad 120. The additive may be provided in different patterns (e.g., regular patterns and/or irregular patterns) on the surface processing pad 120 without deviating from the scope of the present disclosure.

Referring to FIG. 1, the surface processing system 100 includes a workpiece carrier 130. The workpiece carrier 130 is operable to bring one or more semiconductor workpieces 105 into contact with the surface processing pad 120 to implement a surface processing operation. In some examples, the workpiece carrier 130 may be operable to hold a single semiconductor workpiece 105 for single wafer processing. In some examples, the workpiece carrier 130 may be operable to hold a plurality of semiconductor workpieces 105 for batch processing.

The workpiece carrier 130 may be operable to rotate the semiconductor workpiece 105 about an axis 132. The axis 132 is not aligned with the axis 104 associated with the platen 110. The workpiece carrier 130 may be operable to rotate the semiconductor workpiece 105 about the axis 104 in either a clockwise or counterclockwise direction. In some examples, the workpiece carrier 130 may rotate, for instance, at a rotational speed in range of about 15 rpm to about 10000 rpm, such as about 40 rpm to about 7500 rpm, such as about 40 rpm to about 2000 rpm, such as about 40 rpm to about 1000 rpm, such as about 40 rpm to about 500 rpm, such as about 40 rpm to about 120 rpm. Higher rotational speeds, such as between 200 rpm and 10000 rpm may be beneficial for grinding process(s) using a grind disk according to examples of the present disclosure. The workpiece carrier 130 may rotate in the same direction as the platen 110 or in a different direction relative to the platen 110.

The workpiece carrier 130 may be able to provide a downforce 134 on the semiconductor workpiece 105 against the surface processing pad 120. The downforce 134 of the workpiece carrier 130 may be controlled to adjust the surface processing rate (e.g., polishing rate or grind rate) during the surface processing operation of the semiconductor workpiece 105. A higher downforce 134 will result in a faster processing rate. According to examples of the present disclosure, as described in additional detail below, a downforce 134 may be provided to a head of the workpiece carrier 130 independently of a downforce provided to a retaining ring of the workpiece carrier 130.

The workpiece carrier 130 may also oscillate in a lateral direction 135 along the surface of the surface processing pad 120. This will allow exposure of the semiconductor workpiece 105 to different portions of the surface processing pad 120 (e.g., at different radii of the surface processing pad 120) during a surface processing operation (e.g., grinding or polishing).

In some examples, the workpiece carrier 130 may include a head that includes an electrically conductive path of conductive material that may be used to provide a bias (e.g., bias voltage and/or bias current) from a bias source 174 to the semiconductor workpiece 105. Other suitable mechanisms for providing a bias to the workpiece 105 may be implemented without deviating from the scope of the present disclosure.

The surface processing system 100 may include a fluid delivery system 140. The fluid delivery system 140 may be used to deliver a slurry to a surface processing pad 120 held on the platen 110 during a surface processing operation (e.g., ECMP or CMP process). However, during a grind process, such as a coarse grind process or a fine grind process, the fluid delivery system 140 may be configured to deliver a coolant (e.g., deionized water) to the surface of the surface processing pad 120, for instance, through the fluid delivery outlet 142. The fluid delivery system 140 is depicted as having one fluid delivery outlet 142 for purposes of illustration and discussion. Those of ordinary skill in the art, using the disclosures provided herein, will understand that the surface processing system 100 may include multiple fluid delivery outlets arranged to deliver a fluid to the surface of the surface processing pad 120 without deviating from the scope of the present disclosure.

In some examples, the fluid delivery system 140 may include or be coupled to an additive delivery system 145. The additive delivery system 145 may be configured to provide one or more additives with or without the coolant provided to the surface of the surface processing pad 120 through the fluid delivery system 140. In some examples, the additive may be, for instance, one or more of an oxidizing agent, an etchant, an abrasive containing additive, an actuatable additive, a surfactant, or a lubricant. In some examples, the fluid delivery system 140 may include an additive delivery system 145 configured to deliver one or more additives (e.g., oxidizing material, oxide removal material, electrolyte additive) either with the slurry through the fluid delivery outlet 142 or separate from the slurry through the fluid delivery outlet 144. The additive may be provided to the surface of the surface processing pad 120 in other ways without deviating from the scope of the present disclosure. For instance, the surface processing pad 120 may include one or more apertures, pores, perforations, deformation, holes, gaps, etc. to provide an additive to the surface of the surface processing pad 120. In some examples, the additive may be, for instance, one or more of an oxidizing agent, an etchant, an abrasive containing additive, an actuatable additive, a surfactant, or a lubricant.

In some embodiments, the surface processing pad 120 may include one or more apertures, pores, perforations, deformation, holes, gaps, etc. to hold an electrolyte (e.g., electrolyte slurry) or other conductive material to deliver an electrical current. In some examples, portions of the surface processing pad 120 may be porous to retain a fluid additive for a surface processing operation. In some examples, portions of the surface processing pad 120 may be porous to retain an electrolyte (e.g., electrolyte slurry) to provide an electrically conductive path through the surface processing pad 120. In some examples, the surface processing pad 120 may include conductive materials to provide an electrically conductive path through the surface processing pad 120. The conductive materials may include, in some examples, metal materials. The metal materials may contain catalysts that may be used to activate chemistry that contributes to the oxidation of the workpiece 105. Those metals may include, for instance, noble metals, such as platinum, gold, silver, palladium, or other metals and their oxides, such as ruthenium, iridium, iron, nickel, copper, or aluminum. In these cases, the electrical resistivity through a thickness of the surface processing pad 120 can be in the range of 1 micro-Ohm/cm² to 100 milli-Ohm/cm² or higher, and the sheet resistance in a radial direction can be in a range of 6 micro-Ohm m/m to about 250 milli-Ohm m/m or higher.

Referring to FIG. 1, the surface processing system 100 may include a conditioning head 150. The conditioning head 150 may rotate about an axis 152, such that the conditioning head 150 rotates along the surface of the surface processing pad 120 (e.g., in either a clockwise or counterclockwise direction). In some examples, the conditioning head 150 may be on a swing arm 154 that may swing about an axis 156 to move the conditioning head 150 to different locations on the surface processing pad 120. The conditioning head 150 may include an abrasive-containing material that is used to condition or dress the surface processing pad 120 as the surface processing pad 120 is subject to glazing during a surface processing operation. In some examples, the conditioning head 150 may condition the surface processing pad 120 with an additive, such as any of the additives described herein. The additive may be provided to the surface processing pad 120 using a combination of any of the above-described methods and other methods without deviating from the scope of the present disclosure.

To facilitate ECMP, the polishing system 100 may include a workpiece electrode 172 and a bias source 174. The workpiece electrode 172 may include an electrical conductor that provides an electrical contact to, for example, the semiconductor workpiece 105. The workpiece electrode 172 is illustrated as being separate from the workpiece carrier 130 for purposes of illustration and discussion. Those of ordinary skill in the art, using the disclosures provided herein, will understand that the workpiece electrode 172 may be a part of the workpiece carrier 130 (e.g., a metal or electrically conductive path in the workpiece carrier 130 in electrical contact with the semiconductor workpiece 105).

The bias source 174 includes a device or circuit that provides a bias voltage and/or bias current between the semiconductor workpiece 105 (e.g., via the workpiece electrode 172) and the electrolyte of the slurry (e.g., via the surface processing pad 120). For instance, the bias source 174 may be a voltage source configured to provide a controlled bias voltage between the semiconductor workpiece 105 and an electrolyte (e.g., electrolyte slurry, solid electrolyte). The bias source 174 may be a current source configured to provide a controlled bias current to the semiconductor workpiece 105. In some examples, the bias voltage may be in a range of about 0.5 V to about 20 V, such as about 0.5 V to about 2 V, such as about 1V to about 10 V, such as about 8 V to about 20V. In some examples, the workpiece electrode 172 may be placed in physical contact with the workpiece 105, while the bias source 174 may be coupled to an electrolyte solution (e.g., in a slurry) through the surface processing pad 120, the platen 110, or an intermediate layer therebetween.

In some examples, an electrochemical reaction rate on the semiconductor workpiece 105 may be controlled by controlling the bias source 174. For instance, a bias current may be controlled to provide an increased reaction rate or a decreased reaction rate during a surface processing operation. For instance, a high bias current may lead to faster reaction rate and higher polishing rates. However, a lower bias current may lead to a slower reaction rate to allow time for mechanical removal (e.g., through abrasive elements in a slurry) of reactants on the workpiece 105 during the surface processing operation. Control of the bias current may allow for the bias voltage to fluctuate as needed to provide a constant bias current or regulated bias current to the semiconductor workpiece 105.

The system 100 includes one or more control devices, such as a controller 160. The controller 160 may include one or more processors 162 and one or more memory devices 164. The one or more memory devices 164 may store computer-readable instructions that when executed by the one or more processors 162 cause the one or more processors 162 to perform one or more control functions, such as any of the functions described herein. The controller 160 may be in communication with various other aspects of the system 100 through one or more wired and/or wireless control links. The controller 160 may send control signals to the various components of the system 100 (e.g., the platen 110, the workpiece carrier 130, the fluid delivery system 140, the conditioning head 150, the bias source 174) to implement a surface processing operation on the semiconductor workpiece 105.

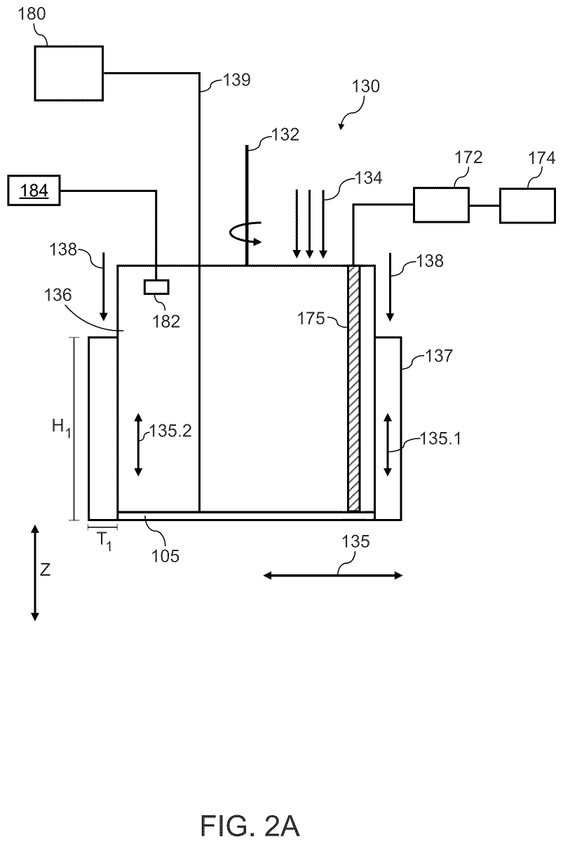

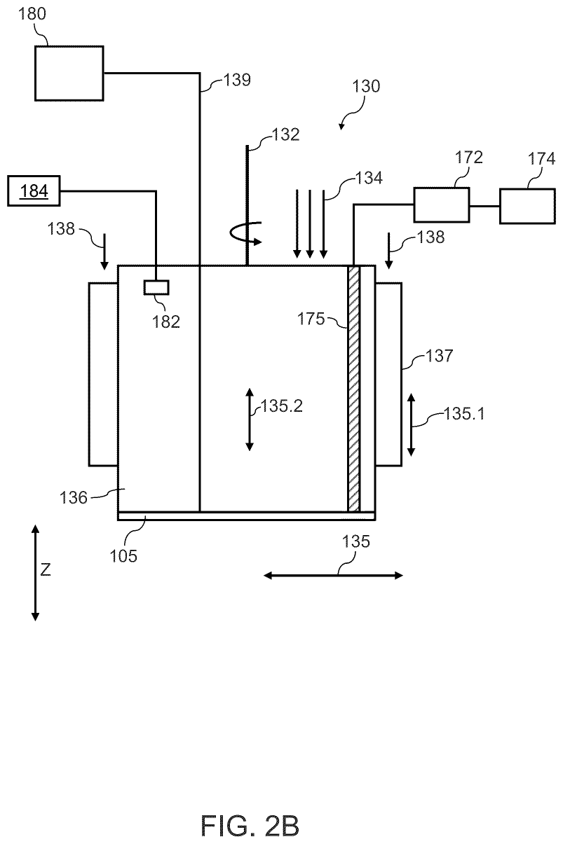

FIG. 2A depicts a cross-sectional view of an example workpiece carrier 130 according to example embodiments of the present disclosure. As depicted, the workpiece carrier 130 includes a head 136 having a retaining ring 137 disposed around at least a portion of the outer circumference of the head 136. The head 136 may be used to press the semiconductor workpiece 105 against the surface processing pad 120 and to rotate the workpiece 105 during a surface processing operation. The retaining ring 137 may be configured to retain the semiconductor workpiece 105 in a position where it is pressed by the head 136 during the surface processing operation.

The retaining ring 137 has a thickness T1. The thickness T1 is the thickness of the retaining ring 137 between an outer diameter and an inner diameter of the retaining ring 137. The thickness T1 may be referred to as the wall thickness of the retaining ring 137. In some examples, the thickness T1 of the retaining ring 137 may be in a range of about 1 mm to about 20 mm, such as about 1 mm to about 10 mm, such as about 2 mm to about 7 mm. A downforce 134 may be applied to the head 136 to provide pressure on the semiconductor workpiece 105 against the surface processing pad 120 during processing. According to examples of the present disclosure, an independent downforce 138 may be applied to the retaining ring 137 during a surface processing operation. For instance, the controller 160 (FIG. 1) may be used to modify the downforce 134 and/or the downforce 138 independently of each other. For instance, the downforce 138 of the retaining ring 137 may be less in magnitude as compared to the downforce 134 of the head 136 during a surface processing operation. In other embodiments, however, the downforce 138 of the retaining ring 137 may be greater in magnitude relative to the downforce 134 of the head 136 during a surface processing operation.

The head 136 may be configured to rotate about axis 132 during the surface processing operation. The retaining ring 137 may also rotate about axis 132 independently of the head 136. For instance, the head 136 may be configured to rotate around the axis 132 in a clockwise manner, while the retaining ring 137 may be configured to rotate around the axis 132 in a counterclockwise manner, or vice versa. The head 136 may be configured to rotate around the axis 132 at a different speed relative to the retaining ring 137. In some examples, the head 136 may rotate around the axis 132 and the retaining ring 137 may not have any rotational movement or negligible rotational movement. In sum, the retaining ring 137 may be rotated or translated independent from the head 136.

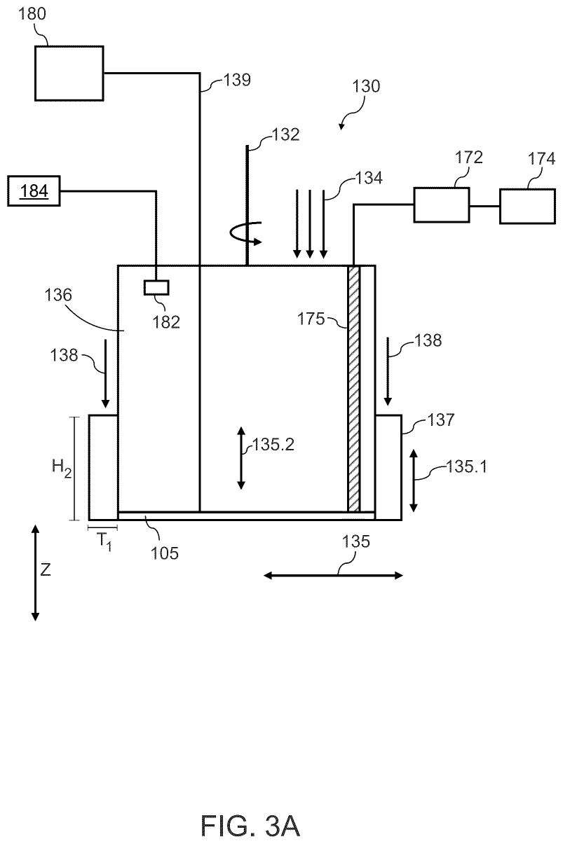

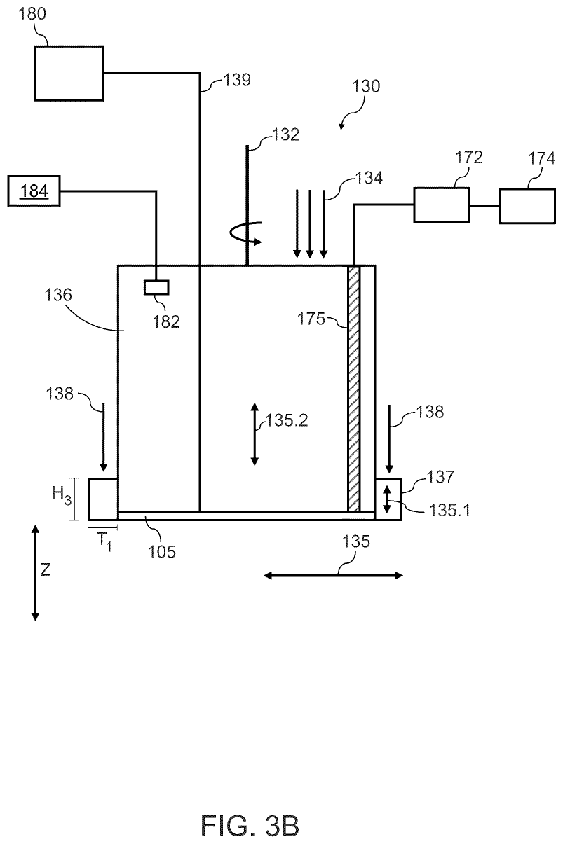

Further, in some examples, one or more of the retaining ring 137 and the head 136 may be movable relative to each other. For instance, in some examples, the retaining ring 137 may be movable as indicated by arrow 135.1 relative to the head 136. In some examples, the head 136 may be movable as indicated by arrow 135.2 relative to the retaining ring 137. In some examples, both the retaining ring 137 and the head 136 are movable relative to each other. In some examples, the retaining ring 137 and/or the head 136 is configured to be moveable in a direction that is generally perpendicular to a surface of the surface processing pad 120. For instance, the retaining ring 137 may be translated in a z-direction independently from the head 136. The head 136 may be translated in a z-direction independently from the retaining ring 137. The z-direction may correspond to a direction generally perpendicular to the surface of the surface processing pad 120. For instance, FIG. 3A depicts the retaining ring 137 in a first vertical position where a surface of the retaining ring 137 may be aligned or co-planar with at least a portion of the semiconductor workpiece 105. FIG. 3B depicts the retaining ring 137 in a second vertical position where a surface of the retaining ring 137 is not generally aligned or co-planar with at least a portion of the semiconductor workpiece 105.

Referring to FIG. 3A, one or more vacuum lines 139 may be disposed within or through the head 136 to provide a vacuum for holding the semiconductor workpiece 105 on the head 136 for surface processing. The vacuum line 139 may be operably connected to a pump or other vacuum source 180 such that a vacuum force may be applied through the vacuum line 139 to the semiconductor workpiece 105. For instance, one or more apertures or pores (not shown) may be disposed in a surface of the head 136 that are in contact with the semiconductor workpiece 105 during processing. In this way, the semiconductor workpiece 105 may be vacuum chucked to the head 136. In addition, and/or in the alternative, at least a portion of the head 136 may include a porous structure that allows a vacuum to be applied through the head 136 to chuck the semiconductor workpiece 105 to the head 136.

In some examples, the head 136 may include a conductive material. For instance, the head 136 may include a conductive path 175. The conductive path 175 may include an electrically conductive and/or a thermally conductive material. The conductive material may include metals (e.g., copper, aluminum), carbon-based materials (e.g., carbon fiber, fabrics, carbon-filled polymers) and/or ceramic materials. The conductive path 175 may facilitate a thermal and/or electrical connection with the semiconductor workpiece 105. The conductive path 175 is illustrated as being a portion of the head 126 in FIGS. 3A and 3B. However, in some examples, a greater portion of the head 136 (e.g., 90% of the head 136) may be a thermally and/or electrically conductive material without deviating from the scope of the present disclosure. As shown in FIG. 2A, the conductive path 175 may be coupled to a workpiece electrode 172 (e.g., or may be the workpiece electrode 172) to provide a bias (e.g. bias voltage or bias current) from a bias source 174 to the semiconductor workpiece 105 during an ECMP operation.

In some embodiments, the head 136 may include one or more cooling channels 182 that are operatively coupled with a cooling system 182 (e.g., fluid based cooling system) that are configured to circulate a fluid (e.g., air, water, coolant) through one or more cooling channels 182 in the head 136 to regulate the temperature of the head 136. During polishing or grinding of silicon carbide semiconductor wafers, generous amounts of heat are generated due to the necessary friction between the surface of the semiconductor workpiece 105 and the surface processing pad 120. In such embodiments, the semiconductor workpiece 105 has one side (e.g., a non-processing side) that is in contact with the head 136 during the surface processing operation. Accordingly, the cooling system 184 may keep the head 136 cooler than the semiconductor workpiece 105 such that the head 136 may heat from the semiconductor workpiece 105 and/or the surface processing pad 120 during a surface processing operation.

The retaining ring 137 may include a wearable material (e.g., a material that is intentionally worn against the surface processing pad during a surface processing operation). In some embodiments, the retaining ring 137 includes a thermoplastic material. The thermoplastic material may include polyethylene, polypropylene, polyurethane, polyarylketones, and combinations thereof. In embodiments, the retaining ring is formed from a polyarylketone. In some embodiments, the polyarylketone is polyether ether ketone.

The retaining ring 137 may also contain an abrasive-containing material that is used to condition or dress the surface processing pad 120 as the surface processing pad is subject to glazing during a surface processing operation (e.g., a grinding operation). The abrasive containing material may include a plurality of abrasive elements (e.g., abrasive particles). In some examples, the host material may include one or more of vitreous material, metal, resin, and/or other sintered material and/or organic material. In some examples, the abrasive elements may be diamond or a diamond coated material. In some examples, the abrasive elements may include a ceramic material. Example ceramic materials may include, for instance, boron carbide (B₄C) and cubic boron nitride (BN). In some examples, the abrasive elements may include one or more metal oxides (sintered and/or unsintered). In some embodiments, the abrasive elements may include silica, ceria, zirconia, alumina, silicon carbide, nitrates, and/or other carbides and in general one or more of: (i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide.

In some examples, the retaining ring 137 may condition the surface processing pad 120 with an additive. The additive may be provided to the surface processing pad using a combination of any of the described methods herein and other methods without deviating from the scope of the present disclosure.

The retaining ring 137 may be configured to at least partially wear away during a surface processing operation. For instance, the height H1 of the retaining ring 137 prior to the surface processing operation is greater than the height H1 of the retaining ring 137 after the surface processing operation.

In some examples, the retaining ring 137 may have an extended height H1 to facilitate the capability of the retaining ring 137 to wear away during surface processing operations without having to replace the retaining ring 137 as often as compared to retaining rings of smaller heights. For instance, the retaining ring 137 may have a height H1 in a range of 1 mm to about 100 mm, such as in a range of about 5 mm to about 100 mm, such as in a range of about 5 mm to about 50 mm, such as in a range of about 5 mm to about 10 mm.

Having a retaining ring 137 with a height H1 of, for instance, 5 mm or greater may allow for longer life of the retaining ring 137 as the retaining ring wears over the course of a plurality of surface processing operations. Because the retaining ring 137 is independently translatable relative to the head 136, the retaining ring 137 may be pressed further down as the retaining ring 137 wears away.

For instance, FIG. 3A depicts the workpiece carrier 130 after at least a portion of the retaining ring 137 has worn away. As can be seen, the retaining ring 137 has a smaller height H2 relative to H1 as a result of wear. However, the retaining ring 137 may be maintained at a vertical position such that a surface of the retaining ring 137 is co-planar with at least a portion of the semiconductor workpiece 130 by virtue of the independent downforce 138 on the retaining ring 137.

FIG. 3B depicts the workpiece carrier 130 after even more of the retaining ring 137 has worn away. As can be seen, the retaining ring 137 has a smaller height H3 relative to H1 and H2 as a result of wear. However, the retaining ring 137 may be maintained at a vertical position such that a surface of the retaining ring 137 is co-planar with at least a portion of the semiconductor workpiece 105 by virtue of the independent downforce 138 on the retaining ring 137.

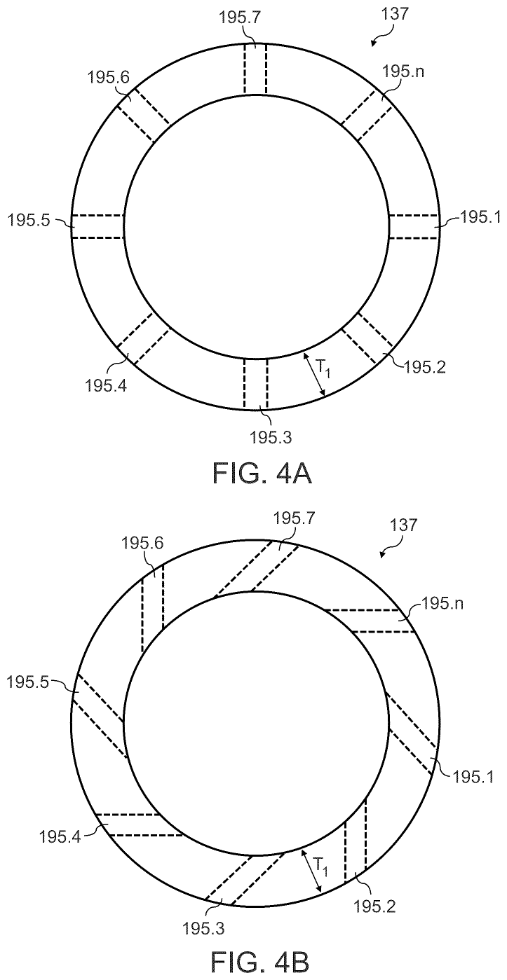

FIGS. 4A and 4B depict top plan views of example retaining rings according to example embodiments of the present disclosure. In some examples, as shown in FIGS. 4A and 4B, a retaining ring 137 may include a plurality of grooves 195 that extend through the wall thickness T1 of the retaining ring 137. The grooves 195 may allow for the delivery of fluid, additives, slurry, or other material to and from a semiconductor workpiece 105 during a surface processing operation. The grooves 195 are illustrated in dashed lines to represent that the grooves are between a top surface of the retaining ring 137 and a bottom surface of the retaining ring 137 and extend through the thickness T1 of the retaining ring 137.

FIG. 4A depicts grooves 195.1, 195.2, 195.3, 194.4, 195.5, 195.6, 195.7, . . . , 195.n extending in a radial direction through the thickness T1 of the retaining ring 137. FIG. 4B depicts grooves 195.1, 195.2, 195.3, 194.4, 195.5, 195.6, 195.7, . . . , 195.n extending at an off-axis angle relative to the through the thickness T1 of the retaining ring 137. The grooves may extend in any direction through the thickness T1 of the retaining ring 137 without deviating from the scope of the present disclosure. Eight grooves 195.1, 195.2, 195.3, 194.4, 195.5, 195.6, 195.7, . . . , 195.n are depicted in FIGS. 4A and 4B. However, the retaining ring 137 may include more or fewer grooves without deviating from the scope of the present disclosure.

To accommodate the wearing away of the material and grooves 195 of the retaining ring 137 during surface processing operations, the retaining ring 137 may include a plurality of sets of grooves at different vertical positions along the retaining ring 137 that are exposed as the retaining ring 137 wears away.

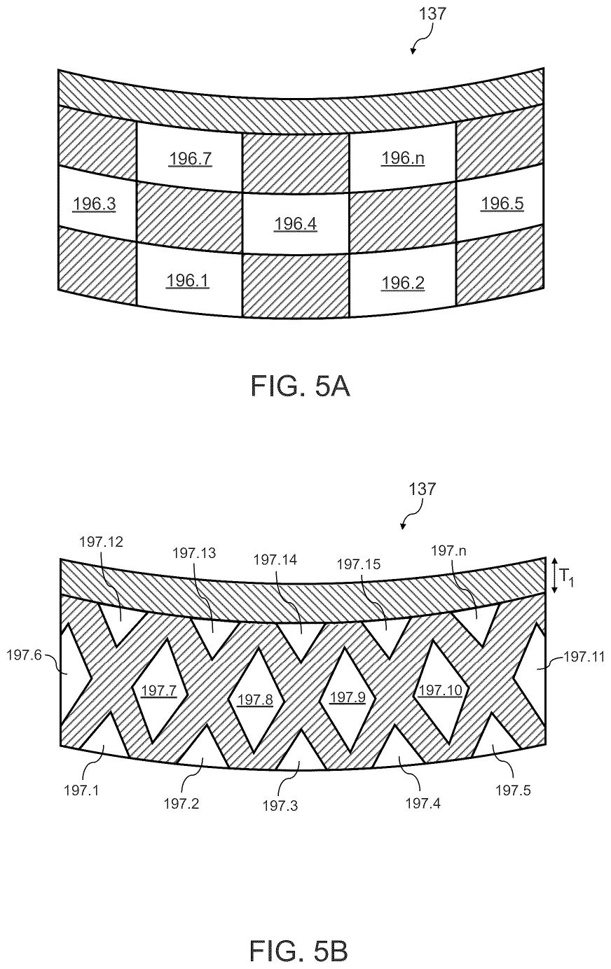

For instance, FIG. 5A depicts a portion of a side view of an example retaining ring 137 with a plurality of grooves 196.1, 196.2, 196.3, 196.4, 196.5, 196.6, 196.7, . . . , 196.n according to example embodiments of the present disclosure. Grooves 196.1, 196.2, 196.3 are at a first vertical height. Grooves 196.3, 196.4, 196.5 are at a second vertical height. Grooves 196.7, 196.n are at a third vertical height. As the retaining ring 137 wears away, grooves 196.1, 196.2 at the first vertical height will be worn away, exposing grooves 196.3, 196.4, 196.5 at the second vertical height. As the retaining ring 137 further wears away, grooves 196.3, 196.4, 196.5 at the second vertical height will be worn away, exposing grooves 196.7, 196.n at the third vertical height. The grooves 196.1, 196.2 at the first vertical height are staggered relative to the grooves 196.3, 196.4, 196.5 at the second vertical height. The grooves 196.7, 196.n at the third vertical height are staggered relative to the grooves 196.3, 196.4, 196.5 at the second vertical height.

For instance, FIG. 5B depicts a portion of a side view of an example retaining ring 137 with a plurality of grooves 197.1, 197.2, 197.3, 197.4, 197.5, 197.6, 197.7, 197.8, 197.9, 197.10, 197.11, 197.12, 197.13, 197.14, 197.15, 197.n according to example embodiments of the present disclosure. Grooves 197.1, 197.2, 197.3, 197.4, 197.5 are at a first vertical height. Grooves 197.6, 197.7, 197.8, 197.9, 197.10, 197.11 are at a second vertical height. Grooves 197.12, 197.13, 197.14, 197.15, 197.n are at a third vertical height. As the retaining ring 137 wears away, grooves 197.1, 197.2, 197.3, 197.4, 197.5 at the first vertical height will be worn away, exposing grooves 197.6, 197.7, 197.8, 197.9, 197.10, 197.11 at the second vertical height. As the retaining ring 137 further wears away, grooves 197.6, 197.7, 197.8, 197.9, 197.10, 197.11 at the second vertical height will be worn away, exposing grooves 197.12, 197.13, 197.14, 197.15, 197.n at the third vertical height.

The grooves 197.1, 197.2, 197.3, 197.4, 197.5 at the first vertical height are staggered relative to the grooves 197.6, 197.7, 197.8, 197.9, 197.10, 197.11 at the second vertical height. The grooves 197.12, 197.13, 197.14, 197.15, 197.n at the third vertical height are staggered relative to the grooves 197.6, 197.7, 197.8, 197.9, 197.10, 197.11 at the second vertical height. The grooves 197 have a shape (e.g., diamond shape and/or triangle shape) such that as the grooves 197.1, 197.2, 197.3, 197.4, 197.5 at the first vertical height and portions of the grooves 197.6, 197.7, 197.8, 197.9, 197.10, 197.11 are exposed, approximately the same cross-sectional area of the grooves 197 may be provided on the surface of the retaining ring 137 for delivery of fluid (e.g., slurry). The retaining ring 137 may include grooves of any shape or size without deviating from the scope of the present disclosure.

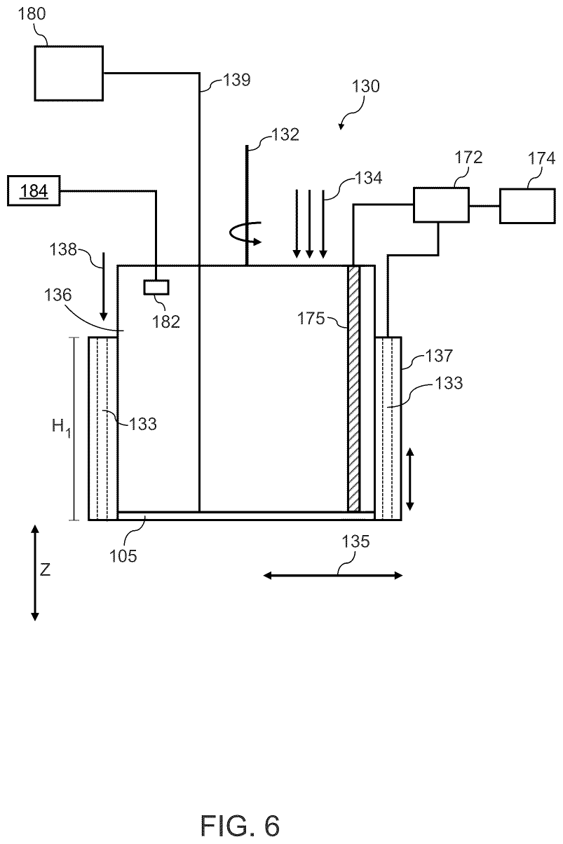

FIG. 6 depicts an example embodiment of a workpiece carrier 130 having a head 136 and a retaining ring 137 according to example embodiments of the present disclosure. The workpiece carrier 130 is similar to the workpiece carrier 130 depicted in FIG. 2A. However, the workpiece carrier 130 includes a retaining ring 137 having a conductive path 133 provided through the retaining ring 137. The conductive path 133 may be a thermally conductive material and/or an electrically conductive material. The conductive material may include one or more metals (e.g., copper, aluminum) and/or carbon-based materials (e.g., carbon fiber, fabrics, carbon-filled polymers) and/or ceramic materials. The conductive path 133, in some examples, may be coupled to a workpiece electrode 172 to provide a bias (e.g., voltage bias and/or current bias) to the semiconductor workpiece 105. In some embodiments, the conductive path 133 may be coupled to the bias source to provide a bias (e.g., voltage bias and/or current bias to the semiconductor workpiece 105.

In some examples, the conductive path 133 may not be electrically coupled to the workpiece 105. For instance, an electrically insulating material may be between the electrically conductive path 133 and the workpiece 105. In these examples, the conductive path 133 of the retaining ring 137 may be used, for instance, to provide a bias (e.g., voltage bias and/or current bias) to an electrolyte (e.g., electrolyte slurry) and/or to the surface processing pad 120. In some examples, the retaining ring 137 may have multiple layers. An inner diameter layer directly on the head 136 may be an electrically insulating material. An outer diameter layer or other layer that is not directly on the head 136 may include a conductive path 133 to provide a bias (e.g., voltage bias and/or current bias) to an electrolyte (e.g., electrolyte slurry) and/or to the surface processing pad 120.

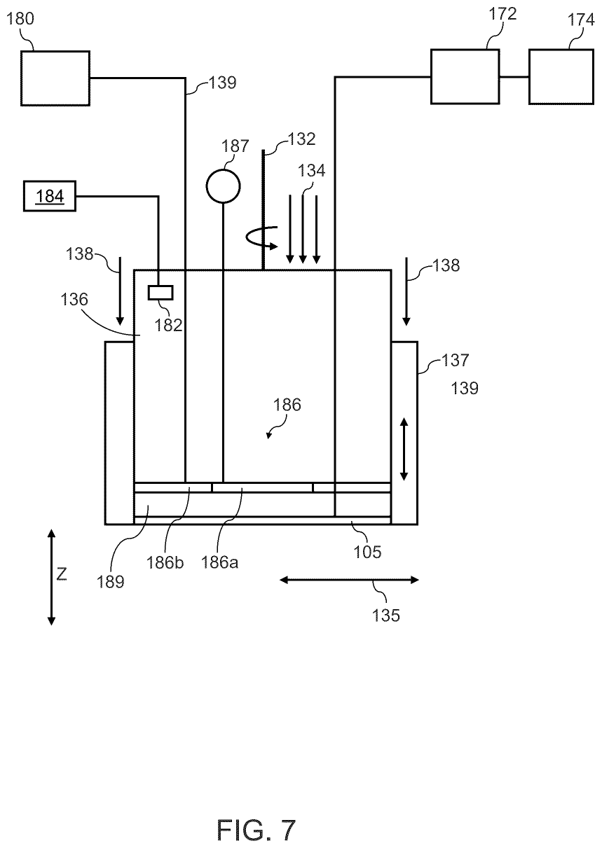

FIG. 7 depicts an example embodiment of a workpiece carrier 130 having a head 136 and a retaining ring 137 according to example embodiments of the present disclosure. The workpiece carrier 130 is similar to the workpiece carrier 130 depicted in FIG. 2A. In the example of FIG. 7, the head 136 may be configured to modify a pressure between the semiconductor workpiece 105 and the surface processing pad 120. For instance, one or more cavities 186 be disposed within the head 136. The one or more cavities 186 may be fluidly coupled to a fluid source 187 that is configured to provide fluid to and from the cavities 186. For instance, when an increase in pressure between the semiconductor workpiece 105 and the surface processing pad 120 is desired, the fluid source 187 may provide fluid into the one or more cavities 186 until the desired pressure is achieved. Further, if a reduction in pressure is required, the fluid source 187 may remove fluid from the one or more cavities 186 until the desired pressure is achieved. Other suitable devices and systems for providing or removing fluid may be utilized herein as known.

In some embodiments, the one or more cavities 186 can include a plurality of cavities (e.g., 186a, 186b, etc.), with each cavity providing its own independently controllable pressure zone. Each pressure zone can provide a different pressure for the semiconductor workpiece 105 against the surface processing pad. As an example, the pressure of a first cavity 186a can be modified independently from a pressure of a second cavity 186b. More particularly, the first cavity 186a and the second cavity 186b may be used for applying different pressures between the surface processing pad and the silicon carbide semiconductor workpiece 105 by creating different pressure zones in the head 136.

More particularly, the first cavity 186a can provide a first pressure zone at a central portion of the workpiece 105. The second cavity 186b can provide a second pressure zone at a peripheral portion of the workpiece 105. If the pressure is too great or too low at the center of the workpiece 105, then the pressure in the first cavity 186a can be modified by providing fluid into or out of the first cavity 186a. Similarly, if the pressure is too great or too low about the periphery of the semiconductor workpiece 105, then the pressure in the second cavity 186b can be modified by providing fluid into or out of the second cavity 186b. While only two separate zones are depicted in FIG. 7, it is understood that additional zones can be added without departing from the scope of the disclosure. For instance, the head may include three pressure zones, four pressure zones, five pressure zones, etc. without deviating from the scope of the present disclosure.

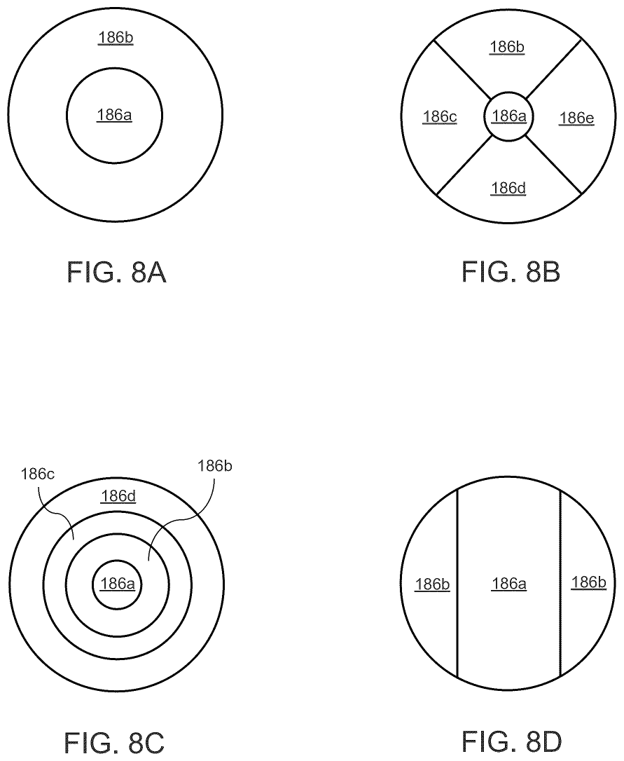

FIGS. 8A-8D depict example arrangements of cavities 186 within the head to provide varying pressure zones according to examples of the present disclosure. For instance, in FIG. 8A, the head has a single central cavity 186a to provide a central pressure zone and a single peripheral cavity 186b to provide a peripheral pressure zone. In FIG. 8B, the head has a single central cavity 186a to provide a central pressure zone and a plurality of peripheral cavities 186b, 186c, 186d, 186e to provide a plurality of peripheral pressure zones at different azimuthal positions relative to the workpiece. In FIG. 8C, the head has a plurality of concentric cavities 186a, 186b, 186c, 186d to provide a plurality of concentric pressure zones. In FIG. 8D, the head has a central cavity 186a that extends across a first portion of the head to provide a first pressure zone and a peripheral cavity 186b that extends across a peripheral portion of the head to provide as a second pressure zone. Other suitable configurations of cavities may be implemented to provide varying pressure zones without deviating from the scope of the present disclosure.

Referring to FIG. 7, the head 136 may also include a cushion layer 189. In some embodiments, the cushion layer 189 can include a thermally conductive layer between the semiconductor workpiece 105 and the one or more cavities 186. In some embodiments, the cushion layer 189 may include an electrically conductive layer between the semiconductor workpiece 105 and the one or more cavities 186.

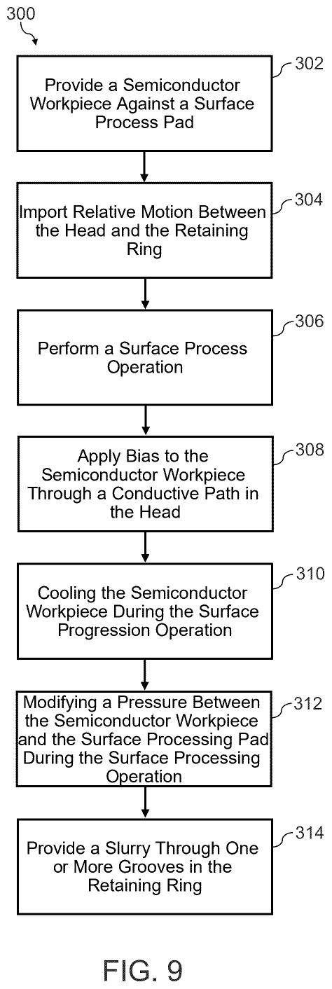

FIG. 9 depicts a flow chart of an example method 300 according to example embodiments of the present disclosure. The method 300 may be implemented, for instance, using the surface processing system 100 of FIG. 1. The method 300 depicts operations performed in a particular order for purposes of illustration and discussion. Those of ordinary skill in the art, using the disclosures provided herein, will understand that the operations of any of the methods described herein may be adapted, expanded, performed simultaneously, omitted, rearranged, include steps not illustrated, and/or modified in various ways without deviating from the scope of the present disclosure.

At 302, the method includes providing a surface of a semiconductor wafer against a surface processing pad in a semiconductor wafer surface processing tool. For instance, the wafer carrier 130 of FIG. 1 may bring a semiconductor workpiece 105 into contact with the surface processing pad 120. The semiconductor workpiece 105 may include 4H silicon carbide, 6H silicon carbide or other crystal structure. The semiconductor workpiece 105 may be doped or undoped.

At 304, the method includes imparting relative motion between the retaining ring 137 and the head 136. For instance, the method may include moving the retaining ring 137 in one or more directions independently from the head 136. The method may include moving the head 137 in one or more directions independently from the retaining ring 137. The method may include moving both the head 136 and the retaining ring 137. For instance, the retaining ring 137 and/or the head 136 may be moved up or down in the z-direction independently from the head 136. Additionally, the downforce 138 applied by the retaining ring 137 on the surface processing pad 120 may be adjusted via moving the retaining ring 137 up or down in the z-direction. In embodiments, the retaining ring 137 may be moved up in the z-direction such that the downforce 138 of the retaining ring 137 on the surface processing pad 120 is less in magnitude than the downforce 134 between the head 136 and the surface processing pad 120. In other embodiments, the retaining ring 137 may be rotated about the axis 132 in a direction that is different from that of the head 136.

At 306, the method includes performing a surface processing operation on the semiconductor wafer. The surface processing operation may include imparting relative motion between the surface processing pad 120 and the semiconductor workpiece 105. For instance, the wafer carrier 130 may rotate the semiconductor workpiece 105 against a rotating platen 110 having a surface processing pad 120 thereon as depicted in FIG. 1.

The surface processing operation may include a grinding operation. In such embodiments, the surface processing pad 120 may be a grind disk such that the system 100 is a grinding system. The grinding operation may be a coarse grinding operation. Coarse grinding operations may be used to reduce a thickness of a silicon carbide semiconductor wafer by about 20 microns to about 200 microns, such by about 20 microns to about 100 microns, such as by about 20 microns to about 80 microns, such as by about 40 microns to about 60 microns, or the like. The grinding operation may be a fine grinding operation. Fine grinding operations may be used to reduce a thickness of a silicon carbide semiconductor wafer by about 0.5 microns to about 20 microns, such as by about 3 microns to about 15 microns, such as by about 5 microns to about 10 microns, or the like.

In other embodiments, the surface processing operation may include a polishing operation. In such embodiments, the surface processing pad may include a polishing pad. Further, the surface treatment process may include CMP or ECMP. The polishing operation may be performed after the grinding operation. For instance, process parameters may be adjusted (e.g., by the controller 160) to switch from performing a grinding operation to a polishing operation using the polishing system 100. As one example, less downforce 134 may be provided by the wafer carrier 130 against the surface processing pad 120 during the polishing operation relative to the grinding operation. In addition, a slurry (with chemical and mechanical abrasive agents) may be provided in the polishing system 100 to perform a polishing operation. The slurry may be provided through fluid delivery system 140 or a separate slurry delivery system. During a grinding operation, a coolant may be provided to the surface of the surface processing pad 120.

In some examples, the polishing system 100 may include multiple platens. A first platen may be for a grinding operation according to examples of the present disclosure. A second platen may be for performing a polishing operation (e.g., using CMP polishing). In some examples, the surface processing pad 120 of the surface processing system may be replaced with a polishing pad to transition from a grinding operation to a polishing operation.

Optionally, the method 300 may include at 308 applying a bias (e.g., bias voltage and/or bias current) to the semiconductor workpiece through a conductive path in the head. For instance, in some embodiments, the workpiece carrier 130 may include a head 136 and a retaining ring 137. The head 136 may include a conductive path of conductive material and may facilitate providing an electrically conductive connection between the semiconductor workpiece 105 and a bias source 174. The conductive material may include metals (e.g., copper, aluminum), carbon-based materials (e.g., carbon fiber, fabrics, carbon-filled polymers) and/or ceramic materials. The structural support provided by the electrically conductive head 136 may facilitate uniform contact between the surface processing pad 120 (e.g., polishing pad) and the wafer being polished. The conductive path of the head 136 may provide an electrical bias (e.g., bias voltage or bias current) to the workpiece during ECMP. The bias source 174 may be coupled to the head 136 such that the electrically conductive path is at least partially through the conductive head 136.

Optionally, the method 300 may include at 310 cooling the semiconductor workpiece and/or other components of the system (e.g., head, surface processing pad) during the surface processing operation. For instance, the head 136 may be coupled to a cooling system 184 that may circulate a cooling fluid through one or more cooling channels 182 in the head 136.

Optionally, the method 300 may include at 312 modifying a pressure between the semiconductor workpiece and the surface processing pad during the surface processing operation. For instance, the pressure applied between the head 136 and the surface processing pad 120 may be adjusted using one or more cavities 186 disposed in the head 136. For instance, to increase pressure between the semiconductor workpiece 105 and the surface processing pad 120, fluid may be provided into the one or more cavities 186, thus increasing the pressure between the semiconductor workpiece 105 and the surface processing pad 120. Similarly, the pressure may be decreased by removing fluid from the one or more cavities 186 in the head 136.

Optionally, the method 300 may include at 314 providing a slurry or other additives through one or more grooves in the retaining ring 137. During the surface processing operation, the surface processing pad 120 is rotating and imparting relative motion with respect to the semiconductor workpiece 105 held by the head 136 and retained by the retaining ring 137. Slurry and other additives are translated and rotated along the surface of the semiconductor workpiece 105 between the semiconductor workpiece and the surface processing pad 120. To avoid buildup of slurry and swarf within the retaining ring 137, grooves are provided in the retaining ring 137 that allow slurry to flow to and away from the semiconductor workpiece 105. Example grooves are depicted in FIGS. 4A, 4B, 5A, and 5B.

Example embodiments of the present disclosure are provided below. Any of the below features or examples may be used in combination with any of the embodiments or features provided in the present disclosure.

In an aspect, the present disclosure provides an example surface processing system. In some implementations, the example surface processing system includes a platen configured to rotate about an axis. In some implementations, the example surface processing system includes a surface processing pad on the platen. In some implementations, the example surface processing system includes a workpiece carrier operable to bring a semiconductor workpiece into contact with the surface processing pad, the workpiece carrier comprising a head and a retaining ring around at least a portion of the head, wherein at least one of the head and the retaining ring is movable relative to each other.

In some implementations of the example surface processing system, the retaining ring is movable in a direction generally perpendicular to a surface of the surface processing pad independently of the head.

In some implementations of the example surface processing system, the surface processing pad includes a polishing pad.

In some implementations of the example surface processing system, the surface processing pad includes a grind disk.

In some implementations of the example surface processing system, the head includes an electrically conductive material.

In some implementations of the example surface processing system, the electrically conductive material provides a conductive path from the semiconductor workpiece to a bias source.

In some implementations of the example surface processing system, the head is operable to provide a vacuum for holding the semiconductor workpiece.

In some implementations of the example surface processing system, the semiconductor workpiece includes a first side that remains in electrically conductive contact with at least a portion of the head during a surface processing operation.

In some implementations of the example surface processing system, the workpiece carrier is operable to provide a first downforce from the head on the surface processing pad that is a different magnitude relative to a second downforce from the retaining ring on the surface processing pad.

In some implementations, the example surface processing system includes one or more cavities in the head, the one or more cavities configured to modify a pressure between the semiconductor workpiece and the surface processing pad.

In some implementations of the example surface processing system, the one or more cavities define a plurality of zones.

In some implementations of the example surface processing system, the one or more cavities each are operable to accommodate a fluid to modify a pressure between the semiconductor workpiece and the surface processing pad.

In some implementations of the example surface processing system, the head includes an electrically conductive layer between the semiconductor workpiece and the one or more cavities.

In some implementations of the example surface processing system, the head includes a thermally conductive layer between the semiconductor workpiece and the one or more cavities.

In some implementations, the example surface processing system includes a cooling system to cool the head.

In some implementations of the example surface processing system, the head is configured to rotate about an axis independently from the retaining ring.

In some implementations of the example surface processing system, the retaining ring includes a thermoplastic material.

In some implementations of the example surface processing system, the thermoplastic material includes a polyaryletherketone.

In some implementations of the example surface processing system, the polyaryletherketone includes polyether ether ketone.

In some implementations of the example surface processing system, the retaining ring includes one or more grooves at different vertical positions along a surface of the retaining ring.

In some implementations of the example surface processing system, the retaining ring includes a wearable material.

In some implementations of the example surface processing system, the retaining ring is operable to at least partially wear away during a surface processing operation.

In some implementations of the example surface processing system, the retaining ring has a wall thickness of about 1 millimeter to about 40 millimeters.

In some implementations of the example surface processing system, the retaining ring includes an abrasive containing material.

In some implementations of the example surface processing system, the abrasive containing material is configured to condition the surface processing pad.

In some implementations of the example surface processing system, the surface processing system includes a conditioning head.

In some implementations, the surface processing system is an electrochemical mechanical polishing (ECMP) system.

In some implementations, the surface processing system is a chemical mechanical polishing (CMP) system.

In some implementations, the surface processing system is a grinding system.

In some implementations of the example surface processing system, the semiconductor workpiece includes silicon carbide.

In an aspect, the present disclosure provides an example method. In some implementations, the example method includes providing a silicon carbide semiconductor workpiece against a surface processing pad with a workpiece carrier, the workpiece carrier includes a head and a retaining ring around at least a portion of the head. In some implementations, the example method includes imparting relative motion between the retaining ring and the head. In some implementations, the example method includes performing a surface processing operation by imparting relative motion between the surface processing pad and the silicon carbide semiconductor workpiece.

In some implementations of the example method, the surface processing pad includes a polishing pad.

In some implementations of the example method, the surface processing pad includes a grind disk.

In some implementations of the example method, the head includes an electrically conductive material.

In some implementations of the example method, the electrically conductive material provides a conductive path from the silicon carbide semiconductor workpiece to a bias source.

In some implementations, the method further includes providing a bias to the silicon carbide semiconductor workpiece through the head.

In some implementations of the example method, the head is operable to create a vacuum for holding the silicon carbide semiconductor workpiece.

In some implementations, the example method includes applying a pressure between the surface processing pad and the silicon carbide semiconductor workpiece utilizing one or more pressure zones in the head.

In some implementations, the example method includes modifying the pressure between the silicon carbide semiconductor workpiece and the surface processing pad by providing or removing fluid to one or more cavities in the head.

In some implementations, the example method includes cooling the head during the surface processing operation.

In some implementations, the example method includes applying a first downforce between the silicon carbide semiconductor workpiece and the surface polishing pad and applying a second downforce between the retaining ring and the surface polishing pad during the surface processing operation, wherein the first downforce is different from the second downforce.

In some implementations, the example method includes rotating the silicon carbide semiconductor workpiece in a first direction and rotating the retaining ring in a second direction, the first direction being different from the second direction.

In some implementations of the example method, the retaining ring at least partially wears away during a surface processing operation.

In some implementations of the example method, the silicon carbide semiconductor workpiece includes a first side that remains in electrically conductive contact with the head during the surface processing operation.

In some implementations, the example method includes providing a slurry through one or more of a plurality of grooves in the retaining ring during the surface polishing operation.

In some implementations, the example method includes conditioning the surface processing pad with abrasive containing material in the retaining ring.

In some implementations of the example method, moving the retaining ring includes moving the retaining ring in a direction generally perpendicular to a surface of the surface processing pad.

In some implementations of the example method, the surface processing operation includes a polishing operation.

In some implementations of the example method, the surface processing operation includes a grinding operation.

In an aspect, the present disclosure provides an example retaining ring for a workpiece carrier in a system for polishing semiconductor workpieces. In some implementations, the example retaining ring includes a plurality of grooves. In some implementations, the plurality of grooves are at different vertical positions along of the retaining ring.

In some implementations of the example retaining ring, the retaining ring has a height of from about 5 millimeters to about 100 millimeters.

In some implementations of the example retaining ring, the retaining ring includes a thermoplastic material.

In some implementations of the example retaining ring, the thermoplastic material includes one or more polyaryletherketones.

In some implementations of the example retaining ring, the retaining ring has a thickness of about 1 millimeter to about 40 millimeters.

In some implementations of the example retaining ring, the retaining ring includes an abrasive containing material.

In some implementations of the example retaining ring, the plurality of grooves are staggered.

In some implementations of the example retaining ring, one or more of the plurality of grooves have a diamond shape.

In an aspect, the present disclosure provides an example surface processing system. In some implementations, the example surface processing system includes a platen operable to rotate about an axis. In some implementations, the example surface processing system includes a surface processing pad on the platen. In some implementations, the example surface processing system includes a bias source. In some implementations, the example surface processing system includes a workpiece carrier operable to bring a semiconductor workpiece into contact with the surface processing pad. The workpiece carrier includes a head and a retaining ring around at least a portion of the head. In some implementations, the head is operable to provide an electrically conductive path through the head to the bias source.

In some implementations of the example surface processing system, the surface processing pad includes a polishing pad.

In some implementations of the example surface processing system, the system further includes a slurry delivery system.

In some implementations of the example surface processing system, the head includes an electrically conductive material.

In some implementations of the example surface processing system, the head is operable to create a vacuum for holding the semiconductor workpiece.

In some implementations of the example surface processing system, the workpiece carrier is operable to provide a first downforce from the head on the surface processing pad that is a different magnitude relative to a second downforce from the retaining ring on the surface processing pad.

In some implementations, the example surface processing system includes one or more cavities in the head, the one or more cavities configured to modify a pressure between the semiconductor workpiece and the surface processing pad.

In some implementations of the example surface processing system, the one or more cavities define a plurality of zones.

In some implementations of the example surface processing system, the head includes an electrically conductive layer between the semiconductor workpiece and the one or more cavities.

In some implementations of the example surface processing system, the head includes a thermally conductive layer between the semiconductor workpiece and the one or more cavities.

In some implementations, the example surface processing system includes a cooling system to cool the head.

In some implementations of the example surface processing system, the head is configured to rotate about an axis independently from the retaining ring.

In some implementations of the example surface processing system, the retaining ring includes a thermoplastic material.

In some implementations of the example surface processing system, the thermoplastic material includes a polyaryletherketone.

In some implementations of the example surface processing system, the polyaryletherketone includes polyether ether ketone.

In some implementations of the example surface processing system, the retaining ring includes one or more grooves.

In some implementations of the example surface processing system, the retaining ring includes a wearable material.

In some implementations of the example surface processing system, the retaining ring is operable to at least partially wear away during a surface processing operation.

In some implementations of the example surface processing system, the retaining ring has a height of about 5 millimeters to about 100 millimeters.

In some implementations of the example surface processing system, the retaining ring includes an abrasive containing material.

In some implementations of the example surface processing system, the abrasive containing material is configured to condition the surface processing pad.

In some implementations of the example surface processing system, the surface processing system is an electrochemical mechanical polishing (ECMP) system.

In some implementations of the example surface processing system, the surface processing system is a chemical mechanical polishing (CMP) system.

In some implementations of the example surface processing system, the surface processing system is a grinding system.

In some implementations of the example surface processing system, the semiconductor workpiece includes silicon carbide.

In an aspect, the present disclosure provides an example retaining ring for a workpiece carrier in a system for polishing semiconductor workpieces. The retaining ring has a height in a range from about 5 millimeters to about 100 millimeters.

In some implementations of the example retaining ring, the retaining ring has a height in a range from about 20 millimeters to about 100 millimeters.

In some implementations of the example retaining ring, the retaining ring includes a thermoplastic material.

In some implementations of the example retaining ring, the thermoplastic material includes one or more polyaryletherketones.

In some implementations of the example retaining ring, the one or more polyaryletherketones comprise polyether ether ketone.

In some implementations of the example retaining ring, the retaining ring has a thickness of about 1 millimeter to about 40 millimeters.

In some implementations of the example retaining ring, the retaining ring includes an abrasive containing material.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A surface processing system for a semiconductor workpiece, comprising:
a platen configured to rotate about an axis;
a surface processing pad on the platen;
a workpiece carrier operable to bring a semiconductor workpiece into contact with the surface processing pad, the workpiece carrier comprising a head and a retaining ring around at least a portion of the head, wherein at least one of the head and the retaining ring is movable relative to each other.

2. The surface processing system of claim 1, wherein the retaining ring is movable in a direction generally perpendicular to a surface of the surface processing pad independently of the head.

3. The surface processing system of claim 1, wherein the surface processing pad comprises a polishing pad.

4. The surface processing system of claim 1, wherein the surface processing pad comprises a grind disk.

5. The surface processing system of claim 1, wherein the head comprises an electrically conductive material.

6. The surface processing system of claim 5, wherein the electrically conductive material provides a conductive path from the semiconductor workpiece to a bias source.

7. The surface processing system of claim 1, wherein the head is operable to provide a vacuum for holding the semiconductor workpiece.

8. The surface processing system of claim 1, wherein the semiconductor workpiece comprises a first side that remains in electrically conductive contact with at least a portion of the head during a surface processing operation.

9. The surface processing system of claim 1, wherein the workpiece carrier is operable to provide a first downforce from the head on the surface processing pad that is a different magnitude relative to a second downforce from the retaining ring on the surface processing pad.

10. The surface processing system of claim 1, comprising one or more cavities in the head, the one or more cavities configured to modify a pressure between the semiconductor workpiece and the surface processing pad.

11. The surface processing system of claim 10, wherein the one or more cavities define a plurality of zones.

12. The surface processing system of claim 10, wherein the one or more cavities each are operable to accommodate a fluid to modify a pressure between the semiconductor workpiece and the surface processing pad.

13. The surface processing system of claim 10, wherein the head comprises an electrically conductive layer between the semiconductor workpiece and the one or more cavities.

14. The surface processing system of claim 10, wherein the head comprises a thermally conductive layer between the semiconductor workpiece and the one or more cavities.

15. The surface processing system of claim 1, comprising a cooling system to cool the head.

16. The surface processing system of claim 1, wherein the retaining ring comprises a thermoplastic material.

17. The surface processing system of claim 1, wherein the retaining ring has a wall thickness of about 1 millimeter to about 40 millimeters.

18. The surface processing system of claim 1, wherein the semiconductor workpiece comprises silicon carbide.

19. A method for surface processing a silicon carbide semiconductor workpiece using a surface processing system, the method comprising:
providing a silicon carbide semiconductor workpiece against a surface processing pad with a workpiece carrier, the workpiece carrier comprising a head and a retaining ring around at least a portion of the head;
imparting relative motion between the retaining ring and the head; and
performing a surface processing operation by imparting relative motion between the surface processing pad and the silicon carbide semiconductor workpiece.

20. A retaining ring for a workpiece carrier in a system for polishing semiconductor workpieces, comprising:
a plurality of grooves;
wherein the plurality of grooves are at different vertical positions along of the retaining ring.
